(19) United States
(12) Patent Application Publication
(10) Pub. No.: US 2007/0164366 A1
(43) Pub. Date: Jul. 19, 2007

(54) Mitigation of gate oxide thinning in dual gate CMOS process technology

(75) Inventors: Xiaoju Wu, Irving, TX (US); Victor Ivanov, Richardson, TX (US); Khan Imran, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 11/331,505

(22) Filed: Jan. 13, 2006

(51) Int. Cl. H01L 29/78; H01L 21/8238

(52) U.S. Cl. 257/369; 438/199; 438/275; 438/981; 257/392

(57) ABSTRACT

Excessive thinning of a thin oxide in a dual gate CMOS fabrication process is mitigated. A thick gate oxide utilized to form high voltage transistors is selectively patterned to leave some thick oxide in an active area where low voltage transistors are formed. Due to fabrication conditions, the thin gate oxide that is formed in an active area where the low voltage transistors are formed may become too thin, particularly in perimeter areas of the low voltage area. Accordingly, the thick gate oxide is patterned so that some of it remains in perimeter areas of the low voltage active area. This mitigates leakage and/or other unwanted conditions that may result if low voltage transistors are formed using the gate oxide that is too thin.

### FIELD OF INVENTION

The present invention relates generally to semiconductor processing, and more particularly to mitigating gate oxide thinning in dual gate CMOS process technology.

### BACKGROUND OF THE INVENTION

Several trends presently exist in the semiconductor and electronics industry. Devices are continually being made smaller, faster and requiring less power. One reason for these trends is that more personal devices are being fabricated that are relatively small and portable, thereby relying on a battery as their primary supply. For example, cellular phones, personal computing devices, and personal sound systems are devices that are in great demand in the consumer market. In addition to being smaller and more portable, personal devices are also requiring increased memory and more computational power and speed. In light of all these trends, there is an ever increasing demand in the industry for smaller and faster transistors used to provide the core functionality of the integrated circuits used in these devices.

Accordingly, in the semiconductor industry there is a continuing trend toward manufacturing integrated circuits (ICs) with higher densities. To achieve high densities, there has been and continues to be efforts toward scaling down dimensions (e.g., at submicron levels) on semiconductor wafers, that are generally produced from bulk silicon. In order to accomplish such high densities, smaller feature sizes, smaller separations between features, and more precise feature shapes are required in integrated circuits (ICs) fabricated on small rectangular portions of the wafer, commonly known as dies. This may include the width and spacing of interconnecting lines, spacing and diameter of contact holes, as well as the surface geometry of various other features (e.g., corners and edges). Additionally, in some instances multiple components are integrated into scaled devises. For example, low voltage and very high voltage transistors are being integrated in the same technology for smart power IC, high voltage mixed signal instrumentation applications. The scaling-down of integrated circuit dimensions can facilitate faster circuit performance and/or switching speeds, and can lead to higher effective yield in IC fabrication by providing more circuits on a die and/or more die per semiconductor wafer. Techniques that facilitate device scaling are thus desirable, particularly where this facilitates integrating multiple components into the same technology.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

Mitigation of gate oxide thinning in dual gate CMOS process technology is disclosed. A thick gate oxide utilized to form high voltage transistors is selectively patterned to leave some thick oxide in an active area where low voltage transistors are formed. Due to fabrication conditions, a thin gate oxide that is formed in an active area where the low voltage transistors are formed may become too thin in perimeter areas of the low voltage area. Accordingly, the thick gate oxide is patterned so that some of it remains in perimeter areas of the low voltage active area. This mitigates leakage and/or other unwanted conditions that may result if low voltage transistors are formed using gate oxide that is too thin.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1 is a flow diagram illustrating an exemplary methodology for mitigating gate oxide thinning in dual gate CMOS process technology according to one or more aspects or embodiments of the present invention.

FIG. 2 is a top view of a semiconductor substrate having active regions formed therein and separated by isolation material according to one or more aspects or embodiments of the present invention.

FIG. 3 is a cross sectional view of the semiconductor substrate of FIG. 2 taken along line 3-3.

FIG. 4 is a top view of a semiconductor substrate wherein thick oxide material is formed within active regions on the substrate according to one or more aspects or embodiments of the present invention.

FIG. 5 is a cross sectional view of the semiconductor substrate of FIG. 4 taken along line 5-5.

FIG. 6 is a top view of a semiconductor substrate wherein thick oxide material is selectively masked off according to one or more aspects or embodiments of the present invention.

FIG. 7 is a cross sectional view of the semiconductor substrate of FIG. 6 taken along line 6-6.

FIG. 8 is a cross sectional view of the semiconductor substrate of FIG. 6 taken along line 8-8.

FIG. 9 is a top view of a semiconductor substrate wherein selectively masked off thick oxide material is removed according to one or more aspects or embodiments of the present invention.

FIG. 10 is a cross sectional view of the semiconductor substrate of FIG. 9 taken along line 10-10.

FIG. 11 is a cross sectional view of the semiconductor substrate of FIG. 9 taken along line 11-11.

FIG. 12 is a top view of a semiconductor substrate after patterned masking material is removed from selectively patterned thick oxide material according to one or more aspects or embodiments of the present invention.

FIG. 13 is a cross sectional view of the semiconductor substrate of FIG. 12 taken along line 13-13.

FIG. 14 is a cross sectional view of the semiconductor substrate of FIG. 12 taken along line 14-14.

FIG. 15 is a top view of a semiconductor substrate wherein thin oxide material is formed according to one or more aspects or embodiments of the present invention.

FIG. 16 is a cross sectional view of the semiconductor substrate of FIG. 15 taken along line 16-16.

FIG. 17 is a cross sectional view of the semiconductor substrate of FIG. 15 taken along line 17-17.

FIG. 18 is a top view of a semiconductor substrate wherein conductive gate electrode material is formed according to one or more aspects or embodiments of the present invention.

FIG. 19 is a cross sectional view of the semiconductor substrate of FIG. 18 taken along line 19-19.

FIG. 20 is a cross sectional view of the semiconductor substrate of FIG. 18 taken along line 20-20.

FIG. 21 is a top view of a semiconductor substrate wherein dual gates may be formed.

FIG. 22 is a cross sectional view of the semiconductor substrate of FIG. 21 taken along line 22-22.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details. In other instances, known structures and devices are shown in block diagram form in order to facilitate describing one or more aspects of the present invention.

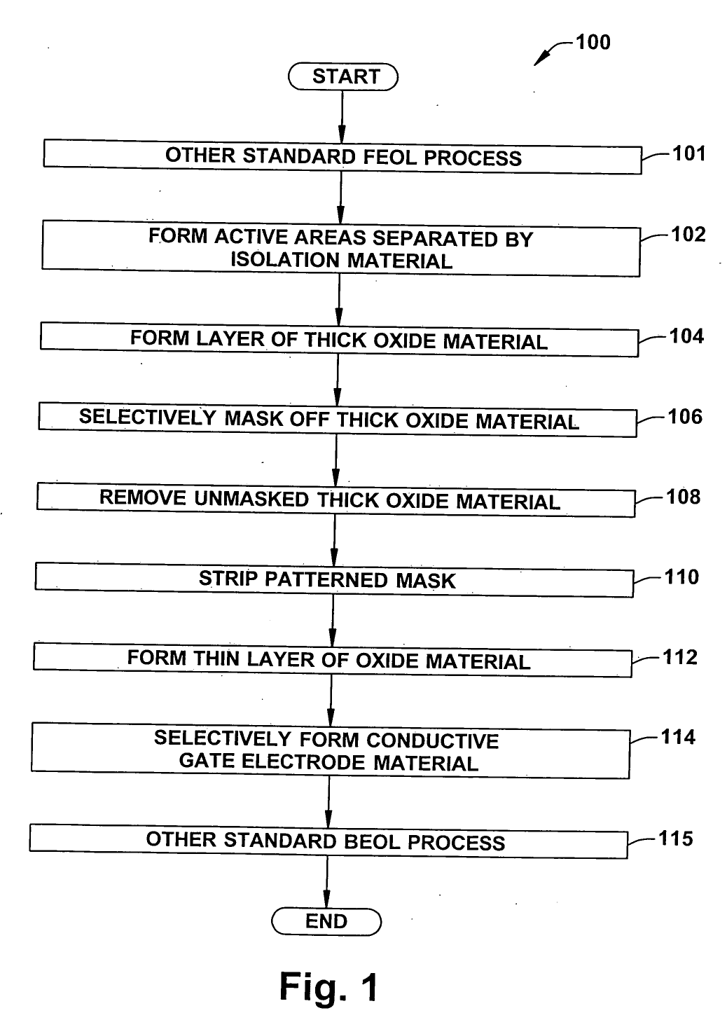

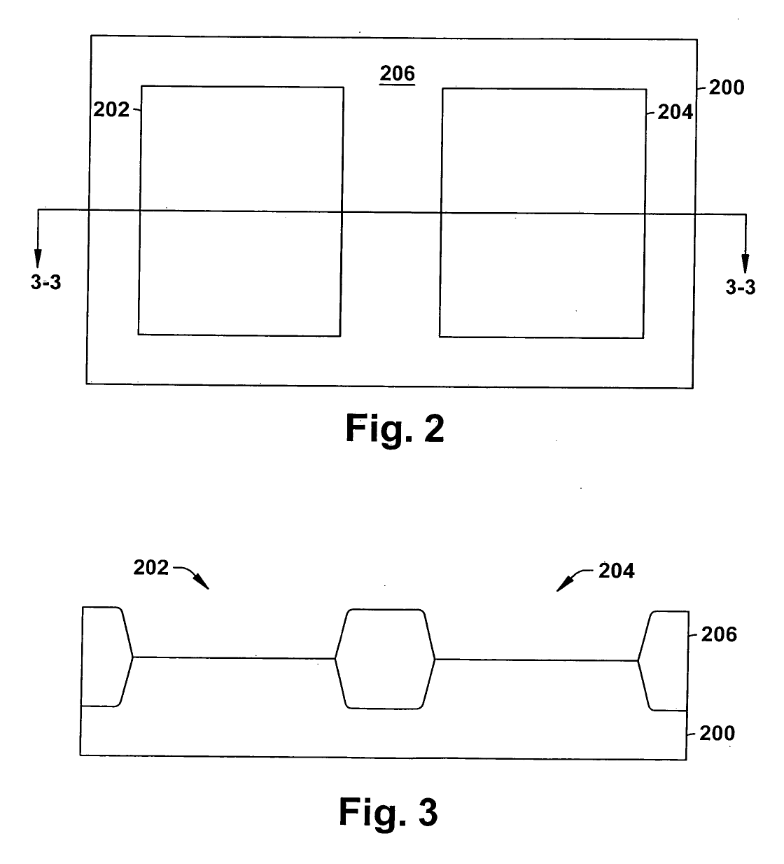

A methodology 100 is illustrated in FIG. 1 for forming dual gate transistors in a CMOS process where over thinning of a gate oxide in a low voltage area is mitigated, and FIGS. 2-20 comprise topical and cross sectional views of a substrate 200 illustrating the implementation of such a method. While the method 100 is illustrated and described below as a series of acts or events, it will be appreciated that the present invention is not limited by the illustrated ordering of such acts or events. For example, some acts may occur in different orders and/or concurrently with other acts or events apart from those illustrated and/or described herein. In addition, not all illustrated steps may be required to implement a methodology in accordance with one or more aspects or embodiments of the present invention. Further, one or more of the acts depicted herein may be carried out in one or more separate acts and/or phases.

Following other standard front end of line (FEOL) processing at 101, active areas 202, 204 are formed within the semiconductor substrate 200 at 102 (FIGS. 2 and 3). The active areas 202, 204 are separated from one another by a non-conductive material 206, which is a field oxide (FOX) in the illustrated example, but may comprise any suitable electrically insulating material, such as STI, LOCOS, etc. It will be appreciated that field oxide material such as that illustrated is generally formed to a thickness of between about 100 nanometers and about 500 nanometers, for example. Additionally, substrate or semiconductor substrate as used herein can include a base semiconductor wafer (e.g., silicon, SiGe, or an SOI wafer) and any epitaxial layers or other type semiconductor layers formed thereover or associated therewith.

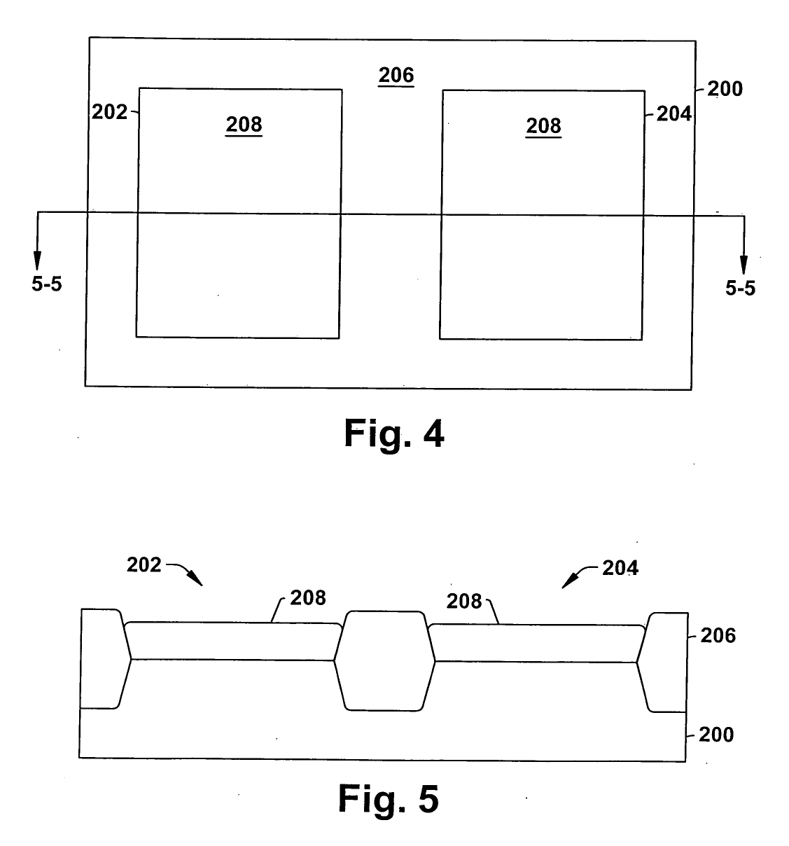

A layer of thick oxide based material 208 is then formed in the active areas 202, 204 at 104 (FIGS. 4 and 5). The thick layer of oxide material 208 may be formed by a thermal growth process, for example, and may be formed to a thickness of between about 900 Angstroms and about 1100 Angstroms, for example, at a temperature of between about 800 degrees Celsius and about 1000 degrees Celsius, for example, in the presence of O₂. It will be appreciated that this thickness is merely an exemplary range.

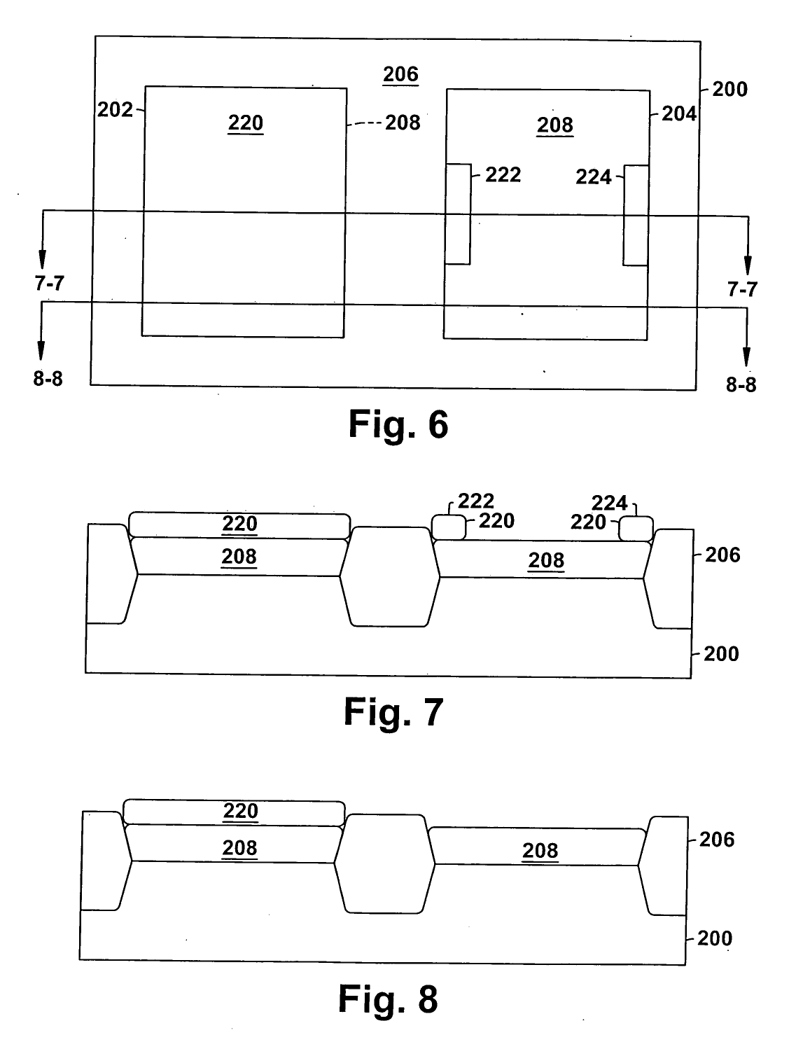

At 106, a layer of masking material 220 is formed over the thick oxide 208 in the active areas 202, 204, and is selectively patterned so as to remain over at least some of the perimeter of an active area (FIGS. 6-8). It will be appreciated that this patterning (as with any and all masking and/or patterning mentioned herein) can be performed in any suitable manner, such as with lithographic techniques, for example, where lithography broadly refers to processes for transferring one or more patterns between various media. In lithography, a light sensitive resist coating (not shown) is formed over one or more layers to which a pattern is to be transferred. The resist coating is then patterned by exposing it to one or more types of radiation or light which (selectively) passes through an intervening lithography mask containing the pattern. The light causes exposed or unexposed portions of the resist coating to become more or less soluble, depending on the type of resist used. A developer is then used to remove the more soluble areas leaving the patterned resist. The patterned resist can then serve as a mask for the underlying layer or layers which can be selectively treated (e.g., etched).

In the illustrated example, the masking material 220 remains over all of the oxide material 208 in active area 202, but only a couple of perimeter portions 222, 224 of the masking material 220 remain over the oxide material 208 in active area 204. It will thus be appreciated that active area 202 corresponds to a region wherein one or more high voltage transistors may be formed where the layer of thick oxide material 208 may be used as a gate dielectric in one or more high voltage transistors. Similarly, area 204 thus corresponds to region where one or more low voltage transistors may be formed where a subsequently formed layer of thin oxide material may be used as a gate dielectric in one or more low voltage transistors. As will be discussed further, the amount of masking material 222, 224 allowed to remain in area 204 is engineered so that gate oxide thinning is mitigated in area 204, but that area 204 is not overwhelmed by residual thick oxide 208. It will also be appreciated that while the masking material 220 is illustrated as merely being over areas 202 and 204, that the masking material 220 can also be formed over the non-conductive material 206.

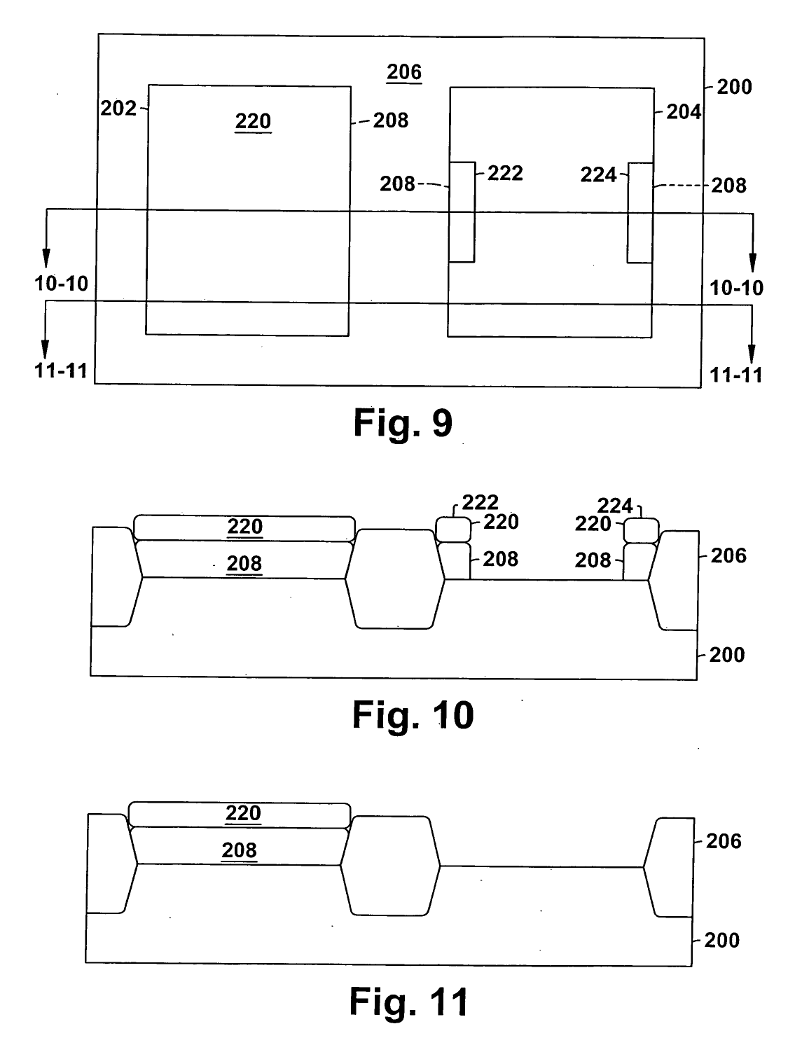

At 108, the un-masked thick oxide material 208 is removed (FIGS. 9-11). It will be appreciated that lead lines for reference characters corresponding to layers underlying other layers are at times presented in phantom in the FIGS., such as reference character 208 in FIGS. 6 and 9. Since the oxide material 208 is masked off in area 202, the material 208 is generally unaffected there. Most of the thick oxide 208 is removed from area 204 however, except where the perimeter portions 222, 224 of the masking material 220 cover the thick oxide 208. It will be appreciated that the thick oxide 208 may be removed via an etching process, for example, and that since the oxide layer 208 is relatively thick such an etching process has to be somewhat aggressive to remove the thick oxide 208 down to the substrate in area 204. For example, a buffered HF deglaze may be utilized for about 8 minutes with an additional about 4 minute over-etch.

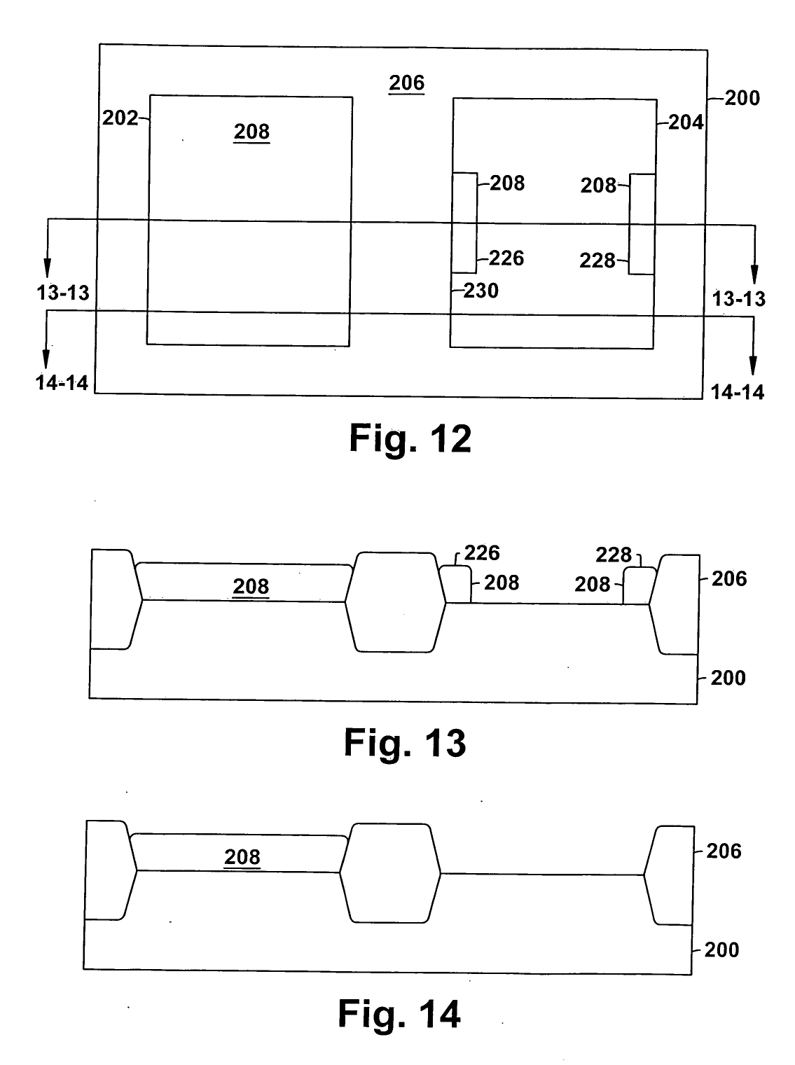

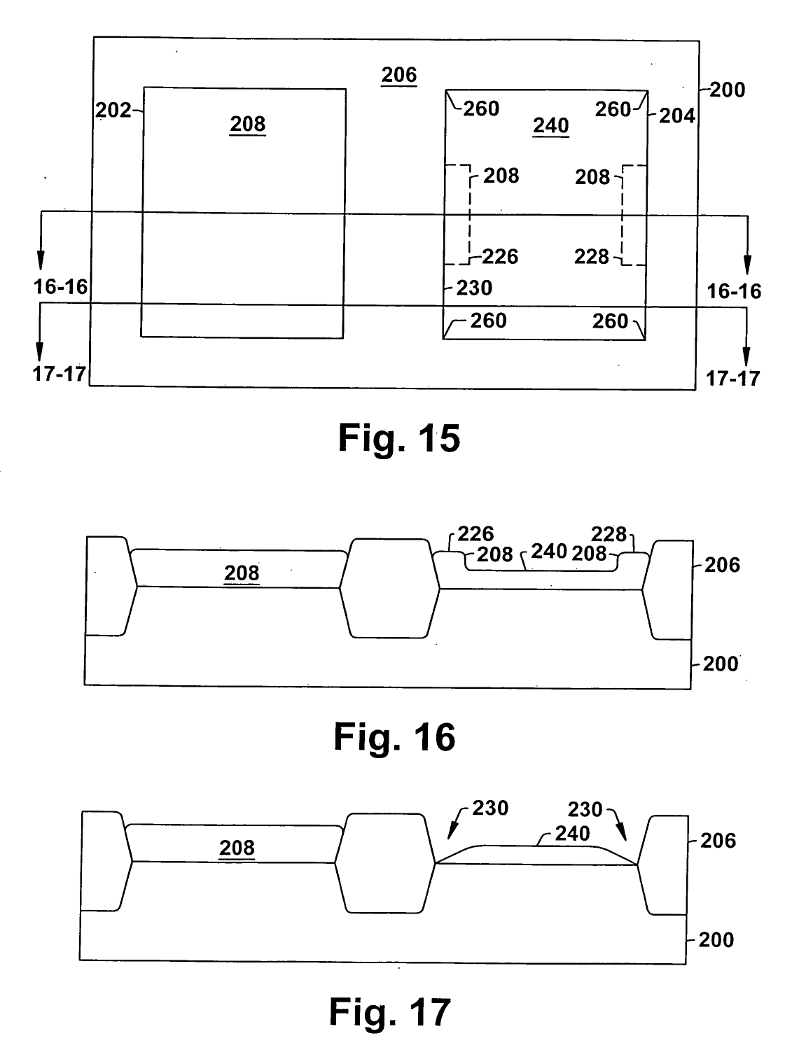

The patterned masking material 220 is then removed (e.g., stripped) at 110 to reveal all of the thick oxide 208 in area 202 and the remaining portions 226, 228 of the thick oxide around the perimeter 230 of area 204 (FIGS. 12-14). After removing the masking material 220, a layer of thin oxide based material 240 is formed at 112 (FIGS. 15-17). As with the thick layer of oxide 208, this thin layer of oxide 240 may be formed by a thermal growth process, for example. The thin layer of oxide 240 may be formed to thickness of between about 100 Angstroms and about 150 Angstroms, for example. While a small amount of additional oxide may grow over the thick layer 208 and/or the FOX 206, the thin layer is generally only formed over the exposed substrate 200 in area 204 since it is the substrate that is partially consumed in forming the oxide 240.

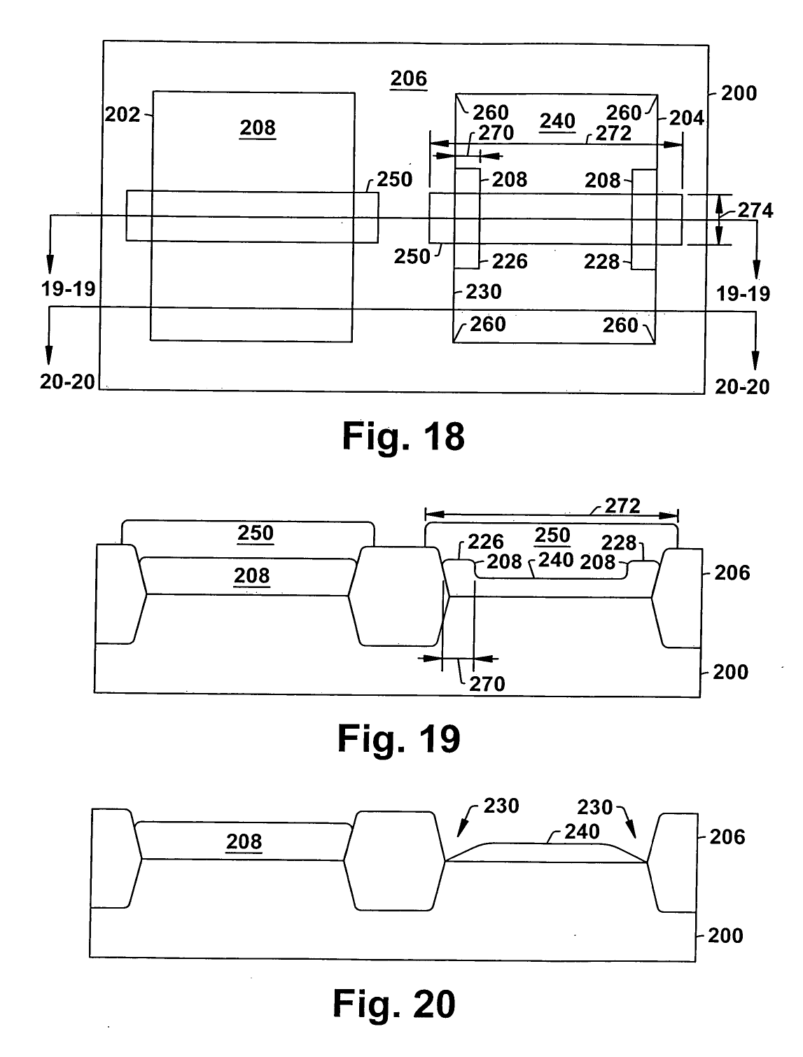

At 114, a conductive material 250 is selectively formed over regions 202 and 204, such as by implementing a patterned masking material (not shown) and/or lithography (FIGS. 18-20). The conductive material 250 generally comprises polysilicon and is utilized to form conductive gate electrodes in one or more transistors formed within active areas 202, 204. In the illustrated example, the conductive material 250 extends over areas 202 and 204 slightly so as to overlap some of the FOX 206. Additionally, the conductive material 250 is situated over active area 204 so that it spans the portions 226, 228 of the thick oxide in area 204.

Note that the layer of thin oxide 240 is not uniform in active area 204. In particular, the thin oxide 240 is thinner around the perimeter 230 of area 204, except, of course, where the remaining portions 226, 228 of the thick oxide 208 persist in area 204 (FIGS. 15-20). The over-thinning of thin layer 240 around the perimeter 230 of area 204 may result from the aggressive etching of the thick oxide layer 208 whereby some of the FOX 206 may also be removed around the perimeter 230 of area 204. The aggressive etching of the thick oxide layer 208 may also contribute to stress and/or charge accumulation at the corners 260 of active region 204 and/or a re-orientation of the crystalline lattice structure of the substrate at the “birds beak” interface of the FOX 206 and the substrate 200 around the perimeter 230 of area 204 (e.g., from a <100> orientation to a <110> orientation), which may slow down the growth rate of the thin oxide 240 around the perimeter 230 of area 204. This reduced oxide growth rate can result in the thin oxide 240 being too thin around the perimeter 230 of area 204. Such an overly thin oxide can have adverse consequence, such as immature oxide breakdown, long term gate oxide reliability, programming and erasing voltage drifts, a reduction in long term data retention, increases in junction leakage, among other things, particularly with regard to nonvolatile memories (e.g., OTP, EPROM, EEPROM).

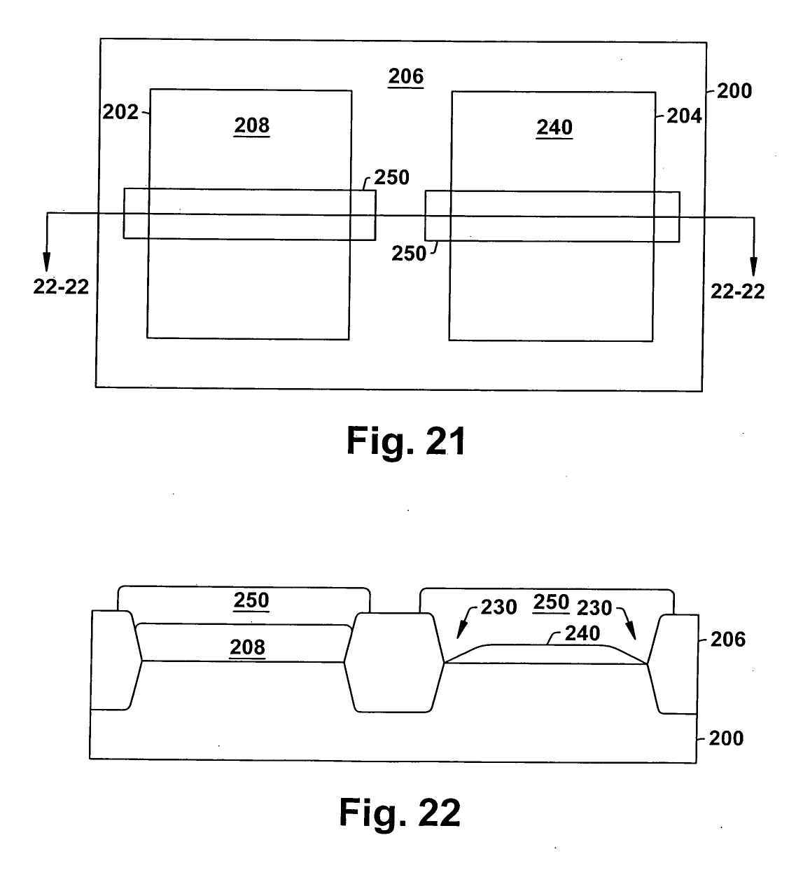

The conductive material 250 is thus formed over the portion of area 204 comprising the remaining portions 226, 228 of the thick oxide 208 so the thickness of the oxide underlying the conductive material 250 is at least as thick as the thin layer of oxide 240 (FIG. 19). This allows one or more low voltage transistors to be formed in area 204 where the thin oxide 240 serves as a gate dielectric and the conductive material 250 (e.g., polysilicon) serves as a gate electrode or electrical contact for the transistors. Such transistors are more reliable and predictable than conventional transistors, at least, with regard to data storage and program voltages since conventional transistors may experience leakage due to overly thin gate dielectrics. FIGS. 21 and 22, for example, illustrate a standard or conventional dual-gate process that is not in accordance with one or more aspects or embodiments of the present invention where thicker oxide 208 is not formed in a low voltage area 204, and thus where a low voltage transistor formed therein may comprise a gate dielectric that is overly thin, particularly around perimeter portions 230 of the low voltage area 204.

After 114, the instant methodology is illustrated as proceeding on to other standard back end of the line (BEOL) processing at 115 and ending thereafter. Generally speaking, to establish CMOS transistors, such as high voltage and low voltage transistors in areas 202 and 204, respectively, a gate structure and source and drain regions are formed after which silicide, metallization, and/or other back-end processing can be performed. As described herein, the gate structure is formed by forming a gate oxide over the upper surface of the substrate 200. The gate electrode (e.g., of polysilicon or other conductive material) is then deposited over the layer of gate oxide material. The polysilicon layer can, for example, for formed to between about 1000 to about 5000 Angstroms, and may include a dopant, such as a p-type dopant (Boron) or n-type dopant (e.g., Phosphorus), depending upon the type(s) of transistors to be formed. The dopant can be in the polysilicon as originally applied, or may be subsequently added thereto (e.g., via a doping process). The gate oxide and gate polysilicon layers are then patterned to form a gate structure, which comprises a gate dielectric and a gate electrode, and which is situated over a channel region in the silicon regions.

With the patterned gate structure formed, LDD, MDD, or other extension implants can be performed, for example, depending upon the type(s) of transistors to be formed, and left and right sidewall spacers can be formed along left and right lateral sidewalls of the patterned gate structure. Implants to form the source (S) region and the drain (D) region are then performed, wherein any suitable masks and implantation processes may be used in forming the source and drain regions to achieve desired transistor types. For example, a PMOS source/drain mask may be utilized to define one or more openings through which a p-type source/drain implant (e.g., Boron (B and/or BF₂)) is performed to form p-type source and drain regions for PMOS transistor devices. Similarly, an NMOS source/drain mask may be employed to define one or more openings through which an n-type source/drain implant (e.g., Phosphorous (P) and/or Arsenic (As)) is performed to form n-type source and drain regions for NMOS transistor devices. Depending upon the types of masking techniques employed, such implants may also selectively dope the poly-silicon of the gate structure of certain transistors, as desired. It will be appreciated that the channel region is thus defined between the source and drain regions in the different transistors. It will also be appreciated that the channel region can be doped prior to forming the gate oxide to adjust Vt's if desired.

It will be appreciated that in addition to facilitating more reliable low voltage transistors, the disclosure herein is also efficient since it requires no additional acts to be performed in a CMOS fabrication process. It also satisfies the ongoing desire to advance device scaling by balancing the need to mitigate gate oxide thinning with the goal of efficiently utilizing valuable semiconductor real estate. For example, the width 270, of the thick oxide 208 left within area 204 is kept to between about 0.08 microns and about 0.12 micros so that the width 272 and length 274 of the conductive material 250 can be reduced to between about 0.7 micros and about 1.1 micros and between about 0.4 microns and about 0.8 microns, respectively, without the thick oxide 208 adversely affecting the operation of one or more low voltage transistors formed in area 204 (FIGS. 18 and 19). This is true even if the thick oxide 208 is left around more of the perimeter 230 of low voltage area 204. For example, the masking material 220 may be selectively patterned so that some of the thick oxide layer 208 remains around all and/or any amount of the perimeter 230 of low voltage area 204 to mitigate over thinning of the oxide 240 at different locations around the perimeter 230 of active area 204 (e.g., from aggressive etching, stress, crystalline re-orientation, etc.).

It will thus be appreciated that mitigating (unwanted) thinning of a gate oxide according to one or more aspects or embodiments of the present invention facilitates concurrent formation of dual gates in a CMOS fabrication process, where this may be desirable in certain instances since dual gates can be utilized to satisfy particular application requirements. For example, the design of an integrated circuit may call for both high voltage and low voltage transistor devices, where such devices have thicker and thinner gate dielectrics, respectively. It will be appreciated that mitigating the overly thin areas of the thin oxide also facilitates more reliable low voltage transistor devices, among other things, because leakage and/or tunneling through overly thin gate oxides is mitigated. This is particularly useful in certain applications, such as where the transistors are utilized as CMOS memory cells in nonvolatile memory such as EPROM, EEPROM, one time programmable (OTP) memory, etc. where data is to be stored and maintained even when power is turned off. Accordingly, data retention is improved. The more uniform thin oxide also allows transistor based memory cells to be programmed in a desired manner since the voltage required to program a transistor based memory cell is generally proportional to the thickness of the gate dielectric. As such, this allows a particular voltage to be reliably used to program memory cells. Additionally, putting pieces of the thick gate dielectric under the poly gate allows a high breakdown voltage to be achieved.

Although the invention has been shown and described with respect to one or more implementations, equivalent alterations and modifications will occur to others skilled in the art based upon a reading and understanding of this specification and the annexed drawings. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. Additionally, the layers can be formed in any number of suitable ways, such as with spin-on techniques, sputtering techniques (e.g., magnetron or ion beam sputtering), (thermal) growth techniques and/or deposition techniques such as chemical vapor deposition (CVD), for example. Further, while a single high voltage active area and a single low voltage active area are illustrated and described herein, it will be appreciated that any number of such areas can be treated as described herein and any number of transistors formed therefrom.

What is claimed is:

1. A method of mitigating over thinning of a low voltage gate dielectric in a dual gate CMOS fabrication process, comprising:
forming a first gate dielectric material to a first thickness in high and low voltage active areas on a semiconductor substrate;
selectively removing some of the first gate dielectric material in the low voltage active area so that some of the first gate dielectric material remains in the low voltage area but some of the substrate is exposed in the low voltage active area;
forming a second gate dielectric material to a second thickness in the low voltage active area over the exposed substrate; and
forming a conductive gate electrode material over at least some of the first gate dielectric material in the high voltage active area and over at least some of the first gate dielectric material and the second gate dielectric material in the low voltage active area.

2. The method of claim 1, where the first thickness is between about 900 Angstroms and about 1100 Angstroms and the second thickness is between about 100 Angstroms and about 150 Angstroms.

3. The method of claim 2, where the remaining first gate dielectric material in the low voltage active area is located around the perimeter of the low voltage active area.

4. The method of claim 3, where the first gate dielectric material remaining in the low voltage active area has a width of between about 0.08 microns and about 0.12 micros.

5. The method of claim 4, where the conductive gate electrode material over the low voltage active area has a width of between about 0.7 micros and about 1.1 micros

6. The method of claim 5, where the conductive gate electrode material over the low voltage active area has a length of between about 0.4 microns and about 0.8 microns.

7. The method of claim 6, where the first and second gate dielectric materials comprise oxide based materials.

8. The method of claim 7, where selectively removing some of the first gate dielectric material in the low voltage active area comprises:
etching the first gate dielectric material with a buffered HF deglaze for about 8 minutes.

9. The method of claim 8, where selectively removing some of the first gate dielectric material in the low voltage active area further comprises:
etching the first gate dielectric material for an additional 4 minutes.

10. The method of claim 8, wherein at least one of forming the first gate dielectric material and forming the second gate dielectric material comprises:
performing a thermal growth process at a temperature of between about 800 degrees Celsius and about 1000 degrees Celsius, for example, in the presence of O₂.

11. The method of claim 10, where the high voltage active area and the low voltage active area are isolated from one another by an electrically non-conductive material on the substrate and where the conductive gate electrode material spans the high voltage active area and the low voltage active area so as to extend over some of the electrically non-conductive material surrounding the high voltage active area and the low voltage active area.

12. The method of claim 11, where the electrically non-conductive material comprises a field oxide material.

13. The method of claim 12, where the conductive gate electrode material comprises polysilicon.

14. The method of claim 11, where the conductive gate electrode material over the high voltage active area has a width of between about 0.7 micros and about 1.1 micros

15. The method of claim 14, where the conductive gate electrode material over the high voltage active area has a length of between about 0.4 microns and about 0.8 microns.

16. The method of claim 15, where selectively removing some of the first gate dielectric material in the low voltage active area further comprises:
forming a masking material over the high and low voltage active areas, where the masking material is patterned over the low voltage active area but not over the high voltage active area.

17. A CMOS transistor comprising:
a gate dielectric overlying a semiconductor substrate;
a conductive gate electrode overlying the gate dielectric;
a channel region within the substrate under the gate dielectric;
a doped source region within the substrate located adjacent to the channel region; and
a doped drain region within the substrate located adjacent to the channel region and opposite the source region, where the gate dielectric has a first thickness in a first region and a second thickness in a second region.

18. The transistor of claim 17, where the first thickness is between about 900 Angstroms and about 1100 Angstroms and the second thickness is between about 100 Angstroms and about 150 Angstroms.

19. The transistor of claim 18, where the transistor is a low voltage transistor.

20. The transistor of claim 19, where the transistor is formed as part of a dual gate fabrication process wherein a high voltage transistor is concurrently formed.
